(19) United States
(12) Patent Application Publication
(10) Pub. No.: US 2005/0253285 A1
(43) Pub. Date: Nov. 17, 2005

(54) Supporting unit for semiconductor manufacturing device and semiconductor manufacturing device with supporting unit installed

(75) Inventors: Akira Kuibira, Itami-shi (JP); Hirohiko Nakata, Itami-shi (JP); Kenji Shinma, Itami-shi (JP)

Correspondence Address: DARBY & DARBY P.C., P. O. BOX 5257, NEW YORK, NY, 10150-5257, US

(73) Assignee: Sumitomo Electric Industries, Ltd., Osaka-shi (JP)

(21) Appl. No.: 11/114,867

(22) Filed: Apr. 26, 2005

(30) Foreign Application Priority Data
Apr. 28, 2004 (JP) 2004-133623

(51) Int. Cl. H01L 23/28

(52) U.S. Cl. 257/787

(57) ABSTRACT

The present invention provides a supporting unit for semiconductor manufacturing device and semiconductor manufacturing device with supporting unit installed wherein there is high thermal uniformity in the support surface for the workpiece and strain to the support section and the support body is prevented. The supporting unit for semiconductor manufacturing device includes: a ceramic support section supporting a workpiece installed in a chamber of a semiconductor manufacturing device; and a hollow support body supporting the support section. The ceramic support section and the support body are hermetically bonded. Either the support body and the chamber are in contact with each other by way of a material with a thermal conductivity lower than that of the support body or the section of the chamber that comes into contact with the support body is a material with a thermal conductivity lower than that of the support body.

### BACKGROUND OF THE INVENTION

1. Field of the Invention

The present invention relates to a supporting unit used in semiconductor manufacturing devices such as etching devices, sputtering devices, plasma CVD devices, low-pressure plasma CVD devices, metal CVD devices, insulative film CVD devices, low-K CVD devices, MOCVD devices, degas devices, ion implantation devices, and coater developers. The present invention also relates to a semiconductor manufacturing devices with such a supporting unit installed.

2. Description of the Background Art

Conventionally, in the production process for semiconductors, various operations such as film formation and etching are performed on a semiconductor substrate (wafer) serving as the workpiece. In semiconductor manufacturing devices performing these operations on semiconductor substrates, a ceramic heater is used to support the semiconductor substrate and heat the semiconductor substrate.

An example of this type of conventional ceramic heater is disclosed in Japanese laid-open patent publication number Hei 4-78138. The ceramic heater disclosed in Japanese laid-open patent publication number Hei 4-78138 includes: a ceramic heater unit formed with an embedded heating resistor, installed in a container, and on which is disposed a wafer heating surface; a convex support unit disposed on the wafer heating surface of the heater and forming a hermetic seal with the container; and an electrode extending outside from the container, connected to the heating resistor, and essentially exposed to the interior space of the container.

In this invention, the ceramic heater and the convex support unit are bonded by glass bonding or the like, and an O-ring provides a hermetic seal between the convex support unit and the container. As a result, the electrode is not exposed to the interior space of the container so that the electrode does not corrode even if a highly corrosive gas, e.g., halogen gas, is used in the semiconductor manufacturing process.

In the semiconductor manufacturing process, the semiconductor substrate is heated, e.g., to 500 deg C., and various operations are performed, but the O-ring can withstand temperatures of up to approximately 200 deg C. Thus, a method such as water-cooling is used on the O-ring side of the convex support unit to provide cooling to approximately 170 deg C. As a result, the bond between the ceramic heater and the support unit is heated, e.g., to 500 deg C., while the O-ring side of the support unit is cooled to approximately 170 deg C. When this is done, the support unit has a temperature distribution between the sides of 170 deg C. to 500 deg C. Because of this temperature distribution, there is a high tensile stress at the bond between the ceramic heater and the support unit. If both the heater and the support unit are formed from ceramic, the tensile stress can lead to destruction of the heater or the support unit due to the brittleness of ceramic.

Japanese laid-open patent publication number 2003-257809 discloses a structure in which there is no bond between the ceramic heater and the support unit. Because the atmospheres in a support member and a container (chamber) are kept essentially the same, however, when a corrosive gas is used the gas enters the support member and can corrode the electrode installed in the support member.

Japanese laid-open patent publication number Hei 04-078138 describes improvements in contamination issues and thermal efficiency issues for metal heaters, a technology that predates ceramic heaters. However, there is no mention of temperature distribution in the semiconductor substrate. Temperature distribution in the semiconductor substrate is important because it is closely related to yield when the various operations described above are performed. Japanese laid-open patent publication number 2001-118664 discloses an example of a ceramic heater that can provide uniform temperature distribution for the ceramic substrate surface. In this invention, it is considered that the structure is practical if the temperature difference between the highest temperature and lowest temperature of the ceramic substrate surface is within a few percent.

In recent years, however, there has been a trend toward larger semiconductor substrates. For example, with silicon wafers, there has been a transition from 8 inches to 12 inches. While a range of ±1.0% has been demanded for the temperature distribution on the heating surface (support surface) for the semiconductor substrate of ceramic heaters, there are now demands of a range of ±0.3% with the increase in silicon substrate diameters.

Furthermore, there has been a trend toward decreased widths in the wiring formed on wafers, and this has been accompanied by a demand for uniformity in the wafer surface temperature. For example, in devices in which a resist film is set after being applied to a wafer by spin coating or the like or where a resist film is set after being developed, where thermal processing is performed at low temperatures no more than 300 deg C., e.g., 200 deg C., a wafer temperature distribution of ±0.3%, preferably ±0.1%, is demanded.

### SUMMARY OF THE INVENTION

The object of the present invention is to overcome these problems and to provide a supporting unit used in semiconductor manufacturing devices that provides a high degree of thermal uniformity on the surface supporting a workpiece, that prevents stress on a support section and supporting unit, and that prevents corrosion to electrodes and the like even if an atmosphere with a corrosive gas is used. Another object of the present invention is to provide a semiconductor manufacturing devices with such a supporting unit installed.

A supporting unit for semiconductor manufacturing devices according to the present invention includes: a ceramic support section installed in a chamber of a semiconductor manufacturing device and supporting a workpiece; and a hollow support body supporting the support section. The ceramic support section and the support body are hermetically bonded. The support body and the chamber are in contact by way of a material having a thermal conductivity that is lower than that of the support body.

According to another aspect, a supporting unit for semiconductor manufacturing devices according to the present invention includes: a ceramic support section installed in a chamber of a semiconductor manufacturing device and supporting a workpiece; and a hollow support body supporting the support section. The ceramic support section and the support body are hermetically bonded. The support body and the chamber are in contact. A section of the chamber that is in contact with the support body is formed from a material having a thermal conductivity that is lower than that of the chamber.

It would be preferable for the material having a thermal conductivity lower than that of the support body to have a thermal conductivity of no more than 30 W/mK. More specifically, it would be preferable for it to be formed from at least one material selected from a group consisting of mullite, mullite/alumina, alumina, and stainless steel. Furthermore, it would be preferable for corrosion-resistant coating to be applied to a surface of the material having a thermal conductivity lower than that of the support body, and it would be preferable for the corrosion-resistant coating to be formed from alumina or aluminum nitride.

It would be preferable for the main component of the ceramic support section to be at least one material selected from a group consisting of aluminum nitride, silicon carbide, silicon nitride, and aluminum oxide. Also, it would be preferable for a heating element to be formed in the ceramic support section and for the main component of the heating element to be at least one material selected from a group consisting of tungsten (W), molybdenum (Mo), platinum (Pt), silver (Ag), palladium (Pd), nickel (Ni), and chrome (Cr).

A semiconductor manufacturing device in which is installed the semiconductor manufacturing device supporting unit described above provides fewer problems involving breakage of the support section and support body and makes it possible to produce high-quality semiconductors and liquid crystals.

According to the present invention, the ceramic support section and the supporting body are hermetically bonded, the support body and the chamber are in contact with each other by way of a material having a thermal conductivity that is lower than that of the support body, or the section of the chamber that is in contact with the support body is formed from a material having a lower thermal conductivity than that of the support body. As a result, the temperature gradient of the support body is significantly changed and the temperature gradient of the connecting section between the ceramic support section and the support body is reduced. When heating, this prevents excessive strain from being applied to the connecting section between the ceramic support section and the support body, thus limiting the possibility of breakage to the ceramic support section and the support body. Also, since a material with a low thermal conductivity is interposed, the heat generated by the heat-generator tends not to escape to the chamber, thus improving the thermal uniformity of the workpiece support surface of the ceramic support section. Compared to conventional devices, semiconductor manufacturing devices in which these supporting units are installed can reduce breakage of the ceramic support section and support body and can improve the characteristics, yield, reliability, and degree of integration of semiconductors and liquid crystals.

### BRIEF DESCRIPTION OF THE DRAWINGS

FIG. 1 is a cross-section showing the structure of an example of a semiconductor manufacturing device supporting unit according to the present invention.

FIG. 2 is a cross-section showing the structure of another example of a semiconductor manufacturing device supporting unit according to the present invention.

FIG. 3 is a cross-section showing the structure of a conventional semiconductor manufacturing device supporting unit according to the present invention.

### DETAILED DESCRIPTION OF THE INVENTION

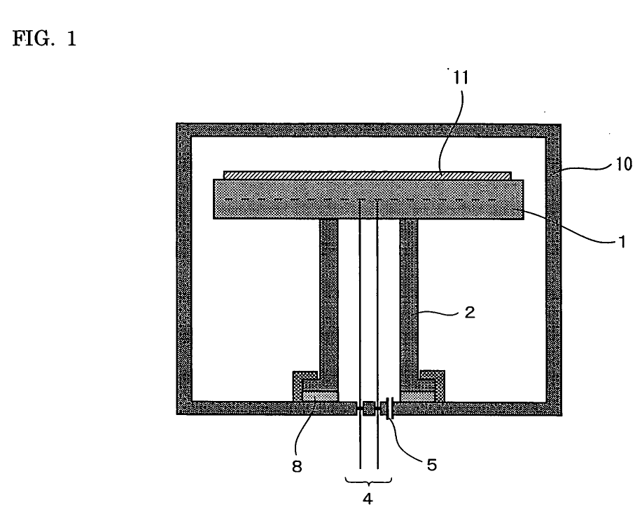

A supporting unit used in semiconductor manufacturing devices will be described, with references to FIG. 1. FIG. 1 shows an embodiment of the present invention. A supporting unit used in semiconductor manufacturing devices includes: a ceramic support section 1 installed in a chamber 10 of a semiconductor manufacturing device and supporting a workpiece 11; and a hollow support body 2 supporting the support section. The ceramic support section and the support body are hermetically bonded, and the support body and the chamber are in contact with each other by way of a material 8 having a low thermal conductivity.

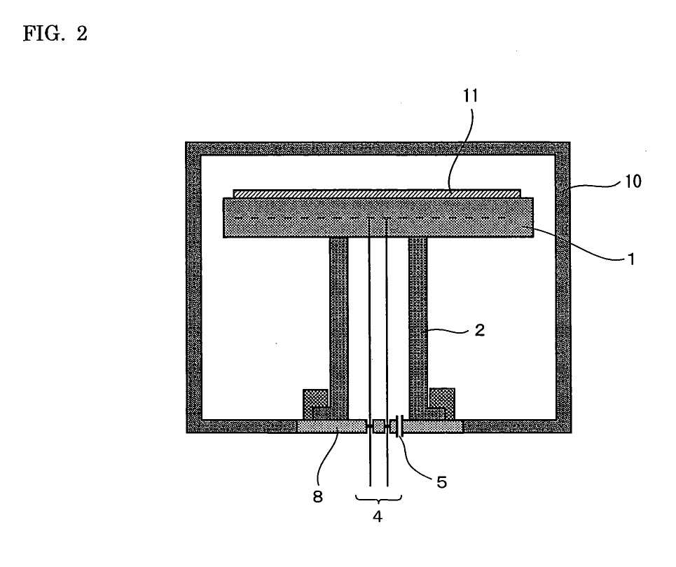

Another embodiment of a supporting unit used in semiconductor manufacturing devices will be described, with references to FIG. 2. FIG. 2 shows another embodiment of the present invention. A supporting unit used in semiconductor manufacturing devices includes: a ceramic support section 1 installed in the chamber 10 of a semiconductor manufacturing device and supporting the workpiece 11; and a hollow support body 2 supporting the support section. The ceramic support section and the support body are hermetically bonded, and the section of the chamber in contact with the support section is formed from the material 8 having a low thermal conductivity.

In the present invention, the support body is in contact with the chamber by way of a material having a thermal conductivity lower than that of the support body. Alternatively, the section of the chamber that is in contact with the support body is formed from a material having a thermal conductivity lower than that of the support body. When the ceramic support section is heated, it is preferably for the ceramic support section to be as thermally uniform as possible. Since the heat of the ceramic support section escapes by way of the support body, it would be preferable for the support body to have a low thermal conductivity. Forming the entire support body from a material with a low thermal conductivity, however, would not change the stress on the bond between the ceramic support section and the support body. For example, if the ceramic support section is heated to 700 deg C. and forced cooling is performed on the chamber, e.g., to 170 deg C., to prevent needless heating of the chamber that would cause thermal deterioration of the chamber, this would reduce heat transmission, but the temperature distribution of the support body would be a gradual distribution from 170 deg C. to 700 deg C.

The present inventors discovered that by having the support body come into contact with the chamber by way of a material having a thermal conductivity lower than that of the support body or by forming the section of the chamber that comes into contact with the support body from a material having a thermal conductivity lower than that of the support body, there is a significant change in temperature distribution with the support body itself and the material with low thermal conductivity, thus making it possible to significantly reduce the stress applied to the bond between the ceramic support section and the support body.

For example, assuming that the ceramic support section is heated to 700 deg C. and the chamber is forcibly cooled to 170 deg C., if the support body has a length of 280 mm, the temperature distribution of the support body will be a gradual change from 170 deg C. at the chamber side to 700 deg C., e.g., with the temperature of the support body at a 20 mm distance from the chamber being 185 deg C. Thus, the temperature gradient on the support body would be AS515 deg C./280 mm. However, if the support body has a length of 260 mm and a material, e.g., with a low thermal conductivity of 1 W/mK, is interposed with a thickness of 20 mm between the chamber and the support body, the temperature at a distance of 20 mm from the chamber would be 465 deg C. Thus, the temperature gradient of the support body would be Δ235 deg C./260 mm, which is significantly lower than when a material with low thermal conductivity is interposed (Δ515 deg C./280 mm). By reducing the temperature distribution of the support body, the thermal stress applied to the bond between the ceramic support section and the support body can be significantly reduced, thus preventing breakage of the ceramic support section or the support body.

Also, in this structure, since the temperature at the chamber-side of the support body increases beyond the temperature rating of a resin O-ring, rather than using an O-ring or the like to hermetically seal the support body 2 and the chamber 10, the support body 2 and the chamber 10 are supported, e.g., by a tool 7, so that the support body does not tilt. It would be preferable to control the pressure inside the support body since if a corrosive gas atmosphere is used, the corrosive gas would otherwise enter the support body and corrode the electrodes 4 or the like. It would be preferable to control the pressure by forming an opening 5 near where the chamber and the support body come into contact and perform vacuuming from the opening 5. Alternatively vacuuming could be performed while introducing an inert gas. Alternatively an inert gas can be introduced.

Since the ceramic support section and the support body are hermetically bonded, the corrosive gas would enter from the unsealed section where the support body and the chamber are in contact with each other. However, with this structure, the corrosive gas would be immediately drawn out by the vacuum or will be pushed out from the support body, thus preventing it from diffusing in the support body and corroding the electrodes and the like installed in the support body.

In the present invention, the references to hermetic bonds and hermetic seals indicates an He leak rate of 10⁻⁸ Pa*m³/s or less. For example, even if the support body and the chamber are secured with a metal gasket, e.g., Al or Ni, that can withstand high temperatures, if the He leak rate is 10⁻⁸ Pa*m³/s or more, it would not be hermetically sealed.

It would be preferable for the support body and the material with low thermal conductivity to be secured by bonding. If these elements are bonded, attached to the chamber would be stable and handling would be easier. It would be preferable for the thermal conductivity of the material with low thermal conductivity is less than that of the support body by 30 W/mK or less, since this allows a high temperature for the section of the support body that comes into contact with the material with low thermal conductivity. It would be preferable for the material with low thermal conductivity to be formed from at least one of the following list: mullite; mullite/alumina; alumina; and stainless steel. This would provide a low thermal conductivity while also providing resistance to heat and corrosion.

Furthermore, it would be more preferable to apply a corrosion-resistant coating to the surface of the material with low thermal conductivity rather than the support body. This allows improved corrosion resistance to be provided easily even if the material has low corrosion resistance. It would be preferable for the material used in the corrosion-resistant coating to be alumina or aluminum nitride. Alumina and aluminum nitride have superior corrosion resistance properties, especially against halogen-based corrosive gases such as fluorine and chlorine, and also have superior heat resistance properties. The corrosion-resistant coating can be formed using a known method such as CVD (chemical vapor deposition), thermal spraying, sputtering, and printing.

It would be preferable for the primary component of the ceramic support section to be ceramic. If uniformity of temperature distribution is to be emphasized, it would be preferable for the ceramic to be silicon carbide or aluminum nitride, which have high thermal conductivity. If reliability is to be emphasized, it would be preferable for the ceramic to be silicon nitride since it is strong and has good thermal shock resistance. If cost is to be emphasized, it would be preferable for the ceramic to be aluminum oxide.

Among these ceramics, aluminum nitride (AlN), which provides high thermal conductivity and superior corrosion resistance, is preferable is performance and cost are to be balanced. In the description below, the production of the wafer support body will be presented using AlN.

It would be preferable for the raw AlN powder to have a specific surface of 2.0-5.0 m²/g. If the specific surface is less than 2.0 m²/g, the sintering of the aluminum nitride would be inadequate. Also, if the value exceeds 5.0 m²/g, the powder will tend to become extremely cohesive, making handling difficult. Furthermore, it would be preferable for the oxygen contained in the raw powder to be 2 wt. % or less. If the oxygen content exceeds 2 wt. %, the thermal conductivity of the sintered product will be reduced. Also, it would be preferable for the metal impurities other than aluminum in the raw powder to be 2000 ppm or less. If the metal impurities exceed this range, the thermal conductivity of the sintered product will be reduced. In particular, Group IV elements such as Si and iron-group elements such as Fe significantly reduce thermal conductivity of the sintered product when present as metal impurities. Thus, their content should be 500 ppm or less.

Since AlN is a material that is difficult to sinter, it would be preferable to add a sintering aid to the raw AlN powder. It would be preferable for the sintering aid to be added to be a rare-earth element compound. Rare-earth element compounds react with aluminum oxides or aluminum oxynitrides present on the surface of aluminum nitride powder particles during sintering and promote the densification of aluminum nitride and eliminate oxygen, which reduces thermal conductivity in the aluminum nitride sintered product. Thus, the thermal conductivity of the aluminum nitride sintered product is improved.

It would be preferable for the rare-earth element compound to be a yttrium compound, which has prominent oxygen removal properties. It would be preferable for the amount added to be 0.01-5 wt. %. If the amount is less than 0.01 wt. %, it becomes difficult to obtain a dense sintered product, and the thermal conductivity of the sintered product is reduced as well. Also, if 5 wt. % is exceeded, sintering aid will be present between the grain boundaries in the aluminum nitride sintered product so that, when a corrosive atmosphere is used, the sintering aid at the grain boundaries is etched, leading to dropped grains and particles. It would be more preferable for the amount of sintering aid added to be 1 wt. % or less. If the amount is 1 wt. % or less, sintering aid will not be present even at the triple point of grain boundaries, thus improving corrosion resistance.

Other rare-earth element compounds that can be used include oxides, nitrides, fluorides, and stearate compounds. Of these, oxides are preferable because they are inexpensive and easy to obtain. Also, stearate compounds are especially preferable because they have a strong affinity to organic solvents so that they can promote mixing if an organic solvent is used to mix raw aluminum nitride powder with sintering aid or the like.

Next, predetermined amounts of solvent, binder, and, if necessary, dispersant and deflocculant, are added and mixed to the raw aluminum nitride powder and sintering aid powder. Examples of mixing methods include bowl mixing and mixing with ultrasonic waves. By mixing in this manner, a raw material slurry is obtained.

The resulting slurry is formed and sintered, resulting in an aluminum nitride sintered product. This can be done either by co-firing or by post-metalizing.

First, the post-metalizing method will be described. Granules are formed from the slurry using a spray dryer or the like. These granules are inserted in a predetermined die and press-formed. It would be preferable for the press pressure to be 9.8 MPa or more. A pressure of less than 9.8 MPa will often result in inadequate strength in the formed product and tends to result in breakage during handling and the like.

The density of the formed product varies depending on the binder content and the amount of sintering aid added, but it would be preferable for the density to be 1.5 g/cm³. If the density is less than 1.5 g/cm³, the distance between the raw particles becomes relative large, making it difficult for sintering to proceeds. Also, if would be preferable for the density of the formed product to be 2.5 g/cm³ or less. If the density exceeds 2.5 g/cm³, the adequate removal of binder from the formed product during the next degreasing step becomes difficult, making it difficult to provide a dense sintered product as described above.

Next, the formed product is heated in a non-oxidizing atmosphere and degreasing is performed. Performing degreasing in an oxidizing atmosphere such as in the open air results in oxidation of the surface of the AlN powder, thus reducing the thermal conductivity of the sintered product. It would be preferable for the non-oxidizing atmosphere gas to be nitrogen or argon. It would be preferable for the heating temperature for the degreasing to be at least 500 deg C. and no more than 1000 deg C. Temperatures less than 500 deg C. result in inadequate removal of binder, leaving excessive carbon residue in the layered body after degreasing which obstructs sintering in the subsequent sintering step. Temperatures exceeding 1000 deg C. result in too little residual carbon, reducing the ability to remove oxygen from the oxide film on the AlN powder surface, reducing the thermal conductivity of the sintered product.

It would be preferable for the carbon left in the formed product after degreasing to be 1.0 wt. % or less. If the residual carbon exceeds 1.0 wt. %, sintering is obstructed and a dense sintered product cannot be obtained.

Next, sintering is performed. Sintering takes place in a non-oxidizing atmosphere, e.g., nitrogen or argon, at a temperature of 1700-2000 deg C. It would be preferable for the moisture contained in the atmosphere gas, e.g., nitrogen, to be −30 deg C. or less at dew point. If moisture content is greater, the AlN reacts with the moisture in the atmosphere gas during sintering, forming an oxynitride and possibly reducing thermal conductivity. Also, it would be preferable for the oxygen content in the atmosphere gas to be 0.001 vol. % or less. If there is too much oxygen, the AlN surface can be oxidized, possibly leading to reduced thermal conductivity.

Furthermore, a boron nitride formed body would be suitable as a tool used in sintering. This BN formed body would have suitable heat resistance to the sintering temperature and the solid lubrication on its surface can minimize the friction between the tool and the layered body while the layered body is contracting during sintering. This makes it possible to obtain a sintered product with little distortion.

The obtained sintered product is treated as necessary. If a conductive paste is to be screenprinted in the next step, it would be preferable for the surface roughness of the sintered product to have an Ra of 5 microns or less. If Ra exceeds 5 microns, the pattern can bleed or pinholes and the like can form when the circuit is being screenprinted. It would be more preferable for the surface roughness to have an Ra of 1 micron or less.

Of course, if both sides of the sintered body will be screenprinted, both sides of the sintered body will be abraded to obtain this surface roughness. However, even if screenprinting is to be performed on only one side, it is better to abrade both sides. If only the side to be screenprinted is abraded, the sintered product will be supported from the unabraded side during screenprinting. There may be projections or contaminants on the unabraded surface so that the securing of the sintered product is unstable, preventing the circuit pattern from being screenprinted well.

Also, it would be preferable for the degree of parallelism between the processed surfaces to be 0.5 mm or less. If the parallelism exceeds 0.5 mm, there can be significant variations in the thickness of the conductive paste during screenprinting. It would be especially preferable if the degree of parallelism is 0.1 mm or less. Furthermore, it would be preferable for the flatness of the surface to be screenprinted to be 0.5 mm or less. If the flatness exceeds 0.5 mm, there can be significant variation in the thickness of the conductive paste. It would be especially preferable if the flatness is 0.1 mm or less as well.

A conductive paste is screenprinted to the abraded sintered product to form the electrical circuit. The conductive paste can be obtained by mixing a metal powder with a solvent and binder and oxide powder as needed. It would be preferable for the metal powder to be tungsten or molybdenum in order to match thermal expansion coefficients with the ceramic.

In order to increase the tightness of the bond with AlN, it is also possible to add oxide powder. It would be preferable for the oxide powder to be an oxide from a group IIIa element or a group IIa element or Al₂O₃, SiO₂, or the like. Especially preferable is yttrium oxide because of its very good wettability in relation to AlN. It would be preferable for the amount of oxide added to be 0.1-30 wt. %. If the amount is less than 0.1 wt. %, the tight bond between the metal layer forming the electrical circuit and AlN is reduced. If the amount exceeds 30 wt. %, the electrical resistance of the metal layer forming the electrical circuit increases.

It would be preferable for the conductive paste to have a thickness of at least 5 microns and no more than 100 microns after drying. If the thickness is less than 5 microns, the electrical resistance becomes too high and the strength of the tight bond is reduced. Also, if the thickness exceeds 100 microns, the strength of the tight bond is reduced.

If the formed circuit pattern is a heater circuit (heat-generating circuit), it would be preferable to have the distance between patterns be at least 0.1 mm. With distances less than 0.1 mm, current leakage can take place when current flows through the heat-generating body depending on the applied potential and the temperature, resulting in a short circuit. In particular, if there is to be use at temperatures of 500 deg C. or higher, it would be preferable to have the distance between patterns be 1 mm or more, and more preferably 3 mm or more.

Next, after degreasing the conductive paste, sintering is performed. Degreasing takes place in a non-oxidizing atmosphere such as nitrogen or argon. It would be preferable for the degreasing temperature to be at least 500 deg C. At temperatures less than 500 deg C., the removal of the binder in the conductive paste is inadequate, leaving a residue of carbon in the metal layer. This results in the formation of a carbide of the metal when sintering is performed, which increases the electrical resistance of the metal layer.

It would be preferable for sintering to be performed in a non-oxidizing atmosphere such as nitrogen or argon at a temperature of 1500 deg C. or more. At temperatures of less than 1500 deg C., the grain growth of the metal powder in the conductive paste does not proceed, resulting in the electrical resistance of the sintered metal layer being too high. Also, it would be preferable for the sintering temperature to not exceed the sintering temperature of the ceramic. If the sintering temperature of the ceramic is exceeded when sintering the conductive paste, the sintering aid contained in the ceramic begins to be emitted, and the grain growth of the metal powder in the conductive paste is promoted so that the tight bond with the metal layer is reduced.

An insulative coat can be formed on the metal layer in order to maintain the insulative property of the formed metal layer. There are no special restrictions on the material for the insulative coat as long as it has low reactivity with the electrical circuit and that its thermal coefficient difference relative to that of AlN is 5.0×10⁻⁶/K or less. For example, glass ceramics or AlN can be used. These material can be used, for example, to form a paste that is screenprinted at a predetermined thickness. Then, after degreasing as needed, sintering can be performed at a predetermined temperature.

It would be preferable for the amount of sintering aid to be 0.01 wt. % or more. If the amount is less than 0.01 wt. %, the insulative coat does not become dense, making it difficult for insulativity to be maintained on the metal layer. Also, it would be preferable for the sintering aid to not exceed 20 wt. %. If the amount exceeds 20 wt. %, the excess infiltrates the metal layer, possibly changing the electrical resistance of the metal layer. There is no special restriction on the thickness to be applied, but it would be preferable for the thickness to be 5 microns or more. If the thickness is less than 5 microns, insulativity becomes difficult to maintain.

The conductive paste can be an alloy or mixture of silver and palladium, platinum, or the like. By adding palladium or platinum to silver, the volume resistivity of the conductor can be increased. Thus, the amount added can be adjusted based on the circuit pattern. Also, these additives have the advantage of preventing migration between circuit patterns. Thus, it would be preferable to add 0.1 parts by weight or more per 100 parts by weight of silver.

It would also be possible to use a mixture or alloy of Ni and Cr for the conductive paste. In particular, adding 20 percent by weight of Cr to Ni increases electrical resistance and provides a heating element with superior heat and corrosion resistance. To decrease costs, 25 percent by weight of Fe can be added. To improve processability, 1 percent by weight of Mn can be added.

In order to maintain adhesiveness to AlN, it would be preferable to add a metal oxide to these metal powders. For example, aluminum oxide or copper oxide, boron oxide, zinc oxide, lead oxide, rare-earth oxides, transitional metal element oxides, alkali-earth metal oxides, and the like can be added. It would be preferable for the amount added to be 0.1 wt. % or more and 50 wt. % or less. It would not be preferable for the content to be less than that since the adhesiveness with aluminum nitride would be reduced. A greater content would not be preferable since sintering of the metal components such as silver would be obstructed.

It would be possible to form a circuit by mixing these metal powders and an inorganic powder, adding an organic solvent and binder, forming a paste, and performing screenprinting as described above. In this case, sintering would be performed in a temperature range of 700 deg C. to 1000 deg C. in an inert gas atmosphere of nitrogen or the like or in the open air.

In order to maintain insulativity between circuits, it would be possible to apply glass ceramics, glazed glass, organic resin, or the like and sinter or set to form an insulative layer. Examples of glasses that can be used include borosilicate glass, lead oxide, zinc oxide, aluminum oxide, and silicon oxide. An organic solvent and binder are added to these powders, a paste is formed, and the paste is applied using screenprinting. There are no special restrictions on the thickness at which the paste is applied, but a thickness of 5 microns or more would be preferable. A thickness of less than 5 microns would make it difficult to maintain insulativity. Also, it would be preferable for the sintering temperature to be lower than the temperature used in forming the circuit as described above. If sintering is performed with a temperature higher than the circuit sintering, it would not be preferable due to large changes in the resistance of the circuit pattern.

Next, ceramic substrates can be stacked as needed. The stack can be formed using a bonding agent. The bonding agent is formed as a paste by adding a group IIa element compound or group IIIa element compound and a binder or solvent to an aluminum oxide powder or aluminum nitride powder, and this paste is applied to the bonding surfaces using screenprinting or the like. There are no special restrictions on the thickness of the bonding agent to be applied, but it would be preferable to use a thickness of 5 microns or more. With a thickness of less than 5 microns, there is a tendency for bonding defects such as pin holes and bonding unevenness to form in the bonding layer.

The ceramic substrates on which the bonding agent is applied is degreased at a temperature of 500 deg C. or more in a non-oxidizing atmosphere. Then, the ceramic substrates to be stacked are layered, a predetermined load is applied, and heat is applied in a non-oxidizing atmosphere to bond the ceramic substrates. It would be preferable for the load to be 5 kPa or more. With a load of less than 5 kPa, an adequate bonding strength cannot be obtained or the bonding defects described above can tend to form.

There are no special restrictions on the heating temperature used for bonding as long as the ceramic substrates can be adequately bonded by the bonding layers, but it would be preferable to use a temperature of 1500 deg C. or more. It would be preferable for the non-oxidizing atmosphere used in degreasing and bonding to be nitrogen, argon, or the like.

By performing the operations described above, a layered ceramic sintered product serving as a wafer supporting unit can be obtained. Rather than using a conductive paste, it would also be possible to form the electrical circuit using molybdenum wire (coil) if it is a heater circuit, or a molybdenum or tungsten mesh if the circuit is an electrostatic adhesion electrode or RF electrode.

In this case, the molybdenum coil or mesh is placed in the raw AlN powder and hot pressing is performed. The hot pressing temperature and atmosphere can be the same as the sintering temperature and atmosphere for the AlN, but it would be preferable for a hotpress pressure of 0.98 MPa or more to be applied. If the pressure is less than 0.98 MPa, there can be gaps between the molybdenum coil or mesh and the AlN, reducing the performance of the heater.

Next, co-firing will be described. A sheet is formed from the raw slurry described above using a doctor blade. There are no special restrictions regarding how to form the sheet, but it would be preferable for the thickness of the sheet to be 3 mm or less after drying. If the sheet thickness exceeds 3 mm, there is greater drying shrinkage of the slurry, increasing the chance of cracks in the sheet.

The metal layer that will form the electrical circuit having a predetermined shape on the sheet is formed by applying a conductive paste using screenprinting or the like. The conductive paste can be the same type used in the description of the post-metalizing method above. However, in the co-firing method, oxide particles can be added to the conductive paste without any disadvantage.

Next, a sheet on which circuits are formed and a sheet on which no circuit is formed are stacked. This is done by setting the sheets at predetermined positions and layering. A solvent can be applied between the sheets if necessary. The stacked structure is heated if necessary. If heating is performed, it would be preferable for the heating temperature to be 150 deg C. or less. If the temperature exceeds this value, the stacked sheets will be significantly deformed. Then, pressure is applied to the stacked sheets to integrate the structure. It would be preferable for the pressure to be in the range of 1-100 MPa. If the pressure is less than 1 MPa, the sheets are not integrated adequately, resulting in peeling in later steps. If the pressure exceeds 100 MPa, the sheets become too deformed.

As in the post-metalizing method described above, this stacked structure is degreased and sintered. The degreasing and sintering temperatures, the amounts of carbon, and the like are the same as in the post-metalizing method. When the conductive paste is printed on the sheets, heater circuits, electrostatic adhesion electrodes, and the like are printed on the sheets, and these are stacked, allowing conductive heaters formed from multiple electrical circuits to be easily created. In this manner, a stacked ceramic sintered product serving as a ceramic support section can be obtained.

If an electrical circuit such as a heat-generating circuit is formed on the outermost layer of the stacked ceramic structure, an insulative coat can be formed on the electrical circuit as in the post-metalizing method described above in order to protect the electrical circuit and maintain insulativity.

The obtained stacked ceramic sintered product is processed as necessary. Generally, the sintered product often does not fall under the precision needed for semiconductor manufacturing units. It would be preferable for the processing precision to be, e.g., 0.5 mm or less for the flatness of the workpiece mounting surface, and more preferably 0.1 mm or less. If the flatness exceeds 0.5 mm, gaps tend to form between the workpiece and the ceramic support section, preventing uniform transfer of heat from the ceramic heater to the workpiece, leading to variations in temperature in the workpiece.

Also, it would be preferable for the surface roughness of the workpiece support surface to have an Ra of 5 microns or less. If the Ra exceeds 5 microns, the friction between the ceramic support section and the workpiece can lead to a large number of dropped AlN grains. The dropped grains become particles that can negatively affect the formation of film on and etching of the workpiece. A surface roughness with an Ra of 1 micron or less is more preferable.

A ceramic support section can be made as described above. Then, the support body is attached to the ceramic support section. There are no special restrictions on the material used in the support body as long as the thermal coefficient does not differ significantly from that of the ceramic in the ceramic support section. However, it would be preferable for the difference of the thermal coefficient from that of the ceramic support section to be 5×10⁻⁶/K or less.

If the thermal coefficient difference exceeds 5×10⁻⁶/K, cracks and the like can form during attachment near the area where the ceramic support section and the support body connect. Even if cracks do not form during bonding, repeated use will lead to thermal cycles being applied to the junction, which can lead to splits and cracks. For example, if the ceramic support section is AlN, AlN would be the most preferable as the material for the support body, but it would also be possible to use silicon nitride, silicon carbide, mullite, or the like.

The attachment is performed using a bonding layer. It would be preferable for the components of the bonding layer to be AlN, Al₂O₃, and a rare-earth oxide. These components provide good wettability with ceramics such as AlN, which is the material in the ceramic support section and the support body, thus providing relatively high bonding strength and also providing easy hermetic sealing of the bonding surface.

It would be preferable for the bonding surfaces of the support body and the ceramic support section to have a flatness of 0.5 mm or less. If this is exceeded, gaps tend to form at the bonding surface, making it difficult to obtain an adequately hermetic seal in the bond. It would be more preferable to have a flatness of 0.1 mm or less. It would be even more preferable for the bonding surface of the ceramic support section to have a flatness of 0.02 mm or less. Also, it would be preferable for the bonding surfaces to have a surface roughness with an Ra of 5 microns or less. If the surface roughness exceeds this value, gaps tend to form in the bonding surface. A surface roughness with an Ra of 1 micron or less is more preferable.

Next, the electrodes are attached to the ceramic support section. Attachment can be performed using known methods. For example, a spot face can be formed from the side of the ceramic support section opposite from the workpiece support surface to the electrical circuit. The electrodes formed from molybdenum, tungsten, or the like can be connected using active brazing metal either with metalization of the electrical circuit or directly without metalization. Then, the electrodes can be plated if necessary to improve oxidation resistance. The semiconductor manufacturing unit supporting unit is made in this manner.

It would also be possible to process semiconductor wafers with the semiconductor manufacturing device supporting unit of the present invention installed in a semiconductor device. The semiconductor manufacturing device supporting unit of the present invention allows high-quality semiconductors and liquid crystals to be manufactured without breakage of the ceramic support section or the support body.

### First Embodiment

A mixture of 99.5 parts by weight of aluminum nitride powder and 0.5 parts by weight of Y₂O₃ powder was prepared. Polyvinyl butyral was used as a binder, and dibutyl phthalate was used as a solvent, with 10 parts by weight and 5 parts by weight being mixed in respectively. The mixture was granulated via spray drying to form granules. These granules were processed by a single-axis press to form two sheets that, after sintering and processing, had a diameter of 350 mm and a thickness of 5 mm.

A mixture of 99.5 parts by weight of aluminum nitride powder and 0.5 parts by weight of Y₂O₃ powder was prepared. Polyvinyl butyral was used as a binder, and dibutyl phthalate is used as a solvent, with 10 parts by weight and 5 parts by weight being mixed in respectively. Plasticizer and dispersant were also mixed in, and the mixture was granulated via spray drying to form granules. These granules were extruded to form a pipe shape that, after sintering and processing, formed an AlN support body with an outer diameter of 60 mm, an inner diameter of 54 mm, and a length of 280 mm. The aluminum nitride powder used here has an average particle diameter of 0.6 microns and a specific surface of 3.4 m²/g.

Both of these shaped products were degreased in a nitrogen atmosphere at 900 deg C. and sintered for five hours in a nitrogen atmosphere at 190 deg C. The obtained sintered products had a thermal conductivity of 180 W/mK. After sintering, the workpiece support surface was abraded to an Ra of 1 micron or less and the support body bonding surface was abraded to an Ra of 5 microns or less. Finishing was also performed on the outer diameters.

A W paste was made using 100 parts by weight of W powder having an average particle diameter of 2.0 microns, 1 part by weight of Y₂O₃, and 5 parts by weight of ethyl cellulose as a binder and butyl carbitol as a solvent. Mixing was performed with an automated mortar and a three-roll rolling mill. This W paste was screenprinted on the AlN sintered product having a 350 mm diameter to form a heater circuit pattern. This was degreased in a nitrogen atmosphere at 900 deg C. and then baked for one hour in a nitrogen atmosphere at 1850 deg C.

A bonding glass in which an ethylene cellulose-based binder is added and mixed in is applied to the other AlN sintered product with 350 mm diameter which was not printed with the heater circuit, and degreasing was performed in a nitrogen atmosphere at 900 deg C. The surface with the heater circuit and the surface on which glass was applied were brought together and bonded by being heated for 2 hours at 1800 deg C. with a load of 0.5 MPa being applied to prevent shifting.

Spot facing was performed from the side opposite from the workpiece support surface to the heater circuit, with a section of the heater circuit left exposed. At one end of the AlN support body, Y₂O₃-based glass used for bonding was applied and set so that the electrodes and lead lines can go inside. Bonding is performed by heating for 1 hour at 1770 deg C. while a load of 5 kPa is applied to prevent shifting. Active brazing metal is used at 850 deg C. to directly bond the electrodes made from W to the exposed heater circuit. The lead lines for forming electrical connections outside of the system are connected. This completes the semiconductor manufacturing device supporting unit formed from the ceramic support section and the support body.

Ten of these types of semiconductor manufacturing device supporting units were formed. As shown in FIG. 1, the supporting unit was clamped to the chamber using a ring 8 formed from the materials shown in Table and having a 60 mm outer diameter, a 54 mm inner diameter, and a 20 mm thickness. The thermal conductivities for AlN shown in Table were obtained by adjusting the amount of Si added.

After heating these supporting units so that the ceramic support sections reached 700 deg C., thermal uniformity was measured. Measuring of thermal uniformity was performed by mounting a 300 mm diameter wafer thermometer on the workpiece support surface and measuring the temperature distribution. The results are shown in Table. Table also shows the thermal conductivity of the ring material. If the ring materials are the same, there was no difference in thermal uniformity between the ten semiconductor manufacturing device supporting units.

TABLE

| | | Thermal conductivity | Thermal uniformity |
|---|---|---|---|
| No. | Ring material | (W/mK) | (%) |
| 1 | Mullite/alumina | 1 | +/− 0.15 |
| 2 | Mullite/alumina | 5 | +/− 0.19 |
| 3 | Stainless steel | 15 | +/− 0.25 |
| 4 | Alumina | 28 | +/− 0.30 |
| 5 | AlN | 35 | +/− 0.40 |
| 6 | AlN | 80 | +/− 0.42 |
| 7 | AlN | 120 | +/− 0.45 |

As can be seen from Table, thermal uniformity is good if the support body and the chamber are brought into contact by way of a material with a thermal conductivity lower than the thermal conductivity of the support body (180 W/mK). It can be seen that thermal conductivity is especially superior with a material having a thermal conductivity lower than 30 W/mK.

Furthermore, the ceramic supporting units were heated to 700 deg C. Then, after stopping heating, the units were cooled to room temperature (25 deg C.). Then, heating was performed to 700 deg C. and then the units were cooled to room temperature again. This cycle was repeated 500 times in a heating cycle test. After the heating cycle test, the connections between the ceramic support sections and the support bodies of the ten supporting units were examined with a stereoscopic microscope, but no irregularities such as cracks were found at all in any of the supporting units.

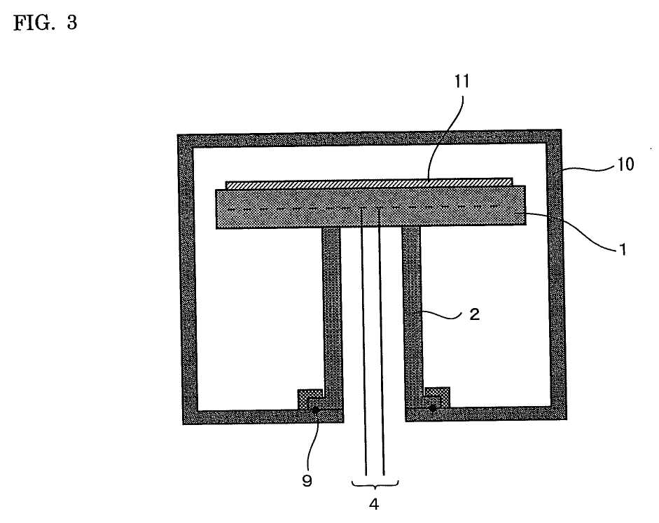

For comparison, ten supporting units were prepared as shown in FIG. 3 with the support bodies sealed hermetically to chambers by way of O-rings 9. The insides of the support bodies were made to be the open-air atmosphere identical to the outside of the chamber. The units were heated to 700 deg C. as described above and thermal uniformity was measured. All the supporting units measured 700 deg C.±0.9%. Also, the 500-cycle test described above was performed. In three of the ten units, the connection between the support section and the support body was completely destroyed. In the remaining seven supporting units, an observation with a stereoscopic microscope of the connection between the support section and the support body of the supporting unit revealed fine cracks in four units.

### Second Embodiment

Supporting units identical to the first embodiment except that the length of the support body was increased by 20 mm to 300 mm were prepared. As shown in FIG. 2, the section of the chamber where the support body comes into contact was formed as a manganese (Mn) plate with a thermal conductivity of 8 W/mK. The support body was clamped as in the first embodiment. Thermal uniformity at 700 deg C. was measured as in the first embodiment and was found to be ±0.21%.

Also, a 500-cycle heating cycle test from room temperature to 700 deg C. as in the first embodiment was performed. No irregularities such as cracks were found in the connection between the support sections and the support bodies in any of the supporting units.

### Third Embodiment

In No. 1 of the first embodiment, a B—Si-based glass preform was interposed between the mullite/alumina and the support body. A load of 5 kPa was applied to prevent shifting and the structure was heated for one hour at 750 deg C. to bond the mullite/alumina and the support body. Otherwise, the structure was identical to that of the first embodiment. The thermal uniformity and cycling test at 700 deg C. were performed as described in the first embodiment were performed. As a result, the thermal uniformity was found to be ±0.17% and no irregularities such as cracks were found in the connection between the support section and the support body after the 500-cycle test.

### Fourth Embodiment

In No. 1 of the first embodiment, a coating of Al₂O₃ on the surface of the mullite/alumina ring was applied by thermal spraying and an AlN coating was applied by CVD. The thickness of the coatings were 20 microns each. Otherwise, the structure was identical to that of the second embodiment. The thermal uniformity and cycling test at 700 deg C. were performed as described in the first embodiment were performed. As a result, the thermal uniformity was found to be ±0.15% and no irregularities such as cracks were found in the connection between the support section and the support body after the 500-cycle test.

Also, a corrosion resistance test was performed by exposing the coated ring to a plasma formed by using 150 W microwaves to excite a gas of CF₄ and O₂. As a result, it was found that corrosion for the uncoated mullite/alumina was 10 microns/h, but was 0.2 microns/h with an Al₂O₃ coating and 0.1 microns/h with an AlN coating. Thus, a significant improvement in corrosion resistance was confirmed.

### Fifth Embodiment

A mixture was prepared with 100 parts by weight of SiC powder, 1.0 part by weight of boron carbide (B₄C) powder and 1.0 part by weight of carbon (C) powder. Polyvinyl butyral was used as a binder, and dibutyl phthalate was used as a solvent, with 10 parts by weight and 5 parts by weight being mixed in respectively. The mixture was granulated via spray drying to form granules. These granules were processed by a single-axis press to form two sheets that, after sintering and processing, had a diameter of 350 mm and a thickness of 5 mm.

A mixture was prepared with 100 parts by weight of SiC powder, 1.0 part by weight of boron carbide (B₄C) powder and 1.0 part by weight of carbon (C) powder. Polyvinyl butyral was used as a binder, and dibutyl phthalate was used as a solvent, with 10 parts by weight and 5 parts by weight being mixed in respectively. Plasticizer and dispersant were also mixed in, and the mixture was granulated via spray drying to form granules. These granules were extruded to form a pipe shape that, after sintering and processing, formed an SiC support body with an outer diameter of 60 mm, an inner diameter of 54 mm, and a length of 300 mm.

The shaped products were degreased at 800 deg C. in an argon atmosphere, and sintering was performed in an argon atmosphere at 2000 deg C. for 6 hours. The obtained sintered products had a thermal conductivity of 150 W/mK. Then, after sintering the workpiece support surfaces were abraded to form an Ra of 1 micron or less and the support body bonding surfaces were abraded to form an Ra of 5 microns or less. Finishing was performed on the outer diameters.

An Ag—Pd paste was made using 100 parts by weight of Ag—Pd powder, 1 part by weight of Y₂O₃, and 5 parts by weight of ethyl cellulose as a binder and butyl carbitol as a solvent. Mixing was performed with a pot mill and a three-roll rolling mill. This Ag—Pd paste was screenprinted on the SiC sintered product having a 350 mm diameter to form a heater circuit pattern. This was degreased in a nitrogen atmosphere at 500 deg C. and then baked for one hour in the open air at 850 deg C.

A B—Si bonding glass in which an ethylene cellulose-based binder is added and mixed in is applied to the other SiC sintered product with 350 mm diameter which was not printed with the heater circuit, and degreasing was performed in the open air at 500 deg C. The surface with the heater circuit and the surface on which glass was applied were brought together and bonded by being heated for 1 hour at 750 deg C. with a load of 0.5 MPa being applied to prevent shifting.

Spot facing was performed from the side opposite from the workpiece support surface to the heater circuit, with a section of the heater circuit left exposed. Active brazing metal was used to directly bond the electrodes made from W to the exposed heater circuit. The lead lines for forming electrical connections outside of the system are connected. This completes the ceramic support section.

At one end of the SiC support body, B—Si-based glass used for bonding was applied and set so that the electrodes and lead lines can go inside. Bonding is performed by heating for 1 hour at 750 deg C. while a load of 5 kPa is applied to prevent shifting. This completes the semiconductor manufacturing device supporting unit.

As shown in FIG. 1, the supporting unit was clamped to the chamber 10 using a mullite/alumina ring so that it is mounted on the bottom of the chamber. Since clamping is the only means used to secure the structure, the end of the support body is free to thermally expand and contract radially relative to the chamber.

Ten of these semiconductor manufacturing device supporting units were produced. As in the first embodiment, thermal uniformity was measured at 700 deg C. The result was 700 deg C. ±0.50% for all supporting units. Cycling tests were also conducted as in the first embodiment and irregularities such as cracks were found in none of the supporting units.

### Sixth Embodiment

A mixture of 100 parts by weight of Al₂O₃ powder and 1.0 parts by weight of magnesium oxide (MgO) powder was prepared. Polyvinyl butyral was used as a binder, and dibutyl phthalate was used as a solvent, with 10 parts by weight and 5 parts by weight being mixed in respectively. The mixture was granulated via spray drying to form granules. These granules were processed by a single-axis press to form two sheets that, after sintering and processing, had a diameter of 350 mm and a thickness of 5 mm.

A mixture of 100 parts by weight of Al₂O₃ powder and 1.0 parts by weight of magnesium oxide (MgO) powder was prepared. Polyvinyl butyral was used as a binder, and dibutyl phthalate is used as a solvent, with 10 parts by weight and 5 parts by weight being mixed in respectively. Plasticizer and dispersant were also mixed in, and the mixture was granulated via spray drying to form granules. These granules were extruded to form a pipe shape that, after sintering and processing, formed an Al₂O₃ support body with an outer diameter of 60 mm, an inner diameter of 54 mm, and a length of 300 mm.

The shaped products were degreased in the open air at 500 deg C. and sintered for 6 hours in the open air at 1500 deg C. The obtained sintered products had a thermal conductivity of 28 W/mK. After sintering, the workpiece support surface was abraded to an Ra of 1 micron or less and the support body bonding surface was abraded to an Ra of 5 microns or less. Finishing was also performed on the outer diameters.

An Ag—Pd paste was made using 100 parts by weight of Ag—Pd powder, 1 part by weight of Y₂O₃, and 5 parts by weight of ethyl cellulose as a binder and butyl carbitol as a solvent. Mixing was performed with a pot mill and a three-roll rolling mill. This Ag—Pd paste was screenprinted on the Al₂O₃ sintered product having a 350 mm diameter to form a heater circuit pattern. This was degreased in the open air at 500 deg C. and then baked for one hour in the open air at 850 deg C.

A B—Si bonding glass in which an ethylene cellulose-based binder is added and mixed in is applied to the other Al₂O₃ sintered product with 350 mm diameter which was not printed with the heater circuit, and degreasing was performed in the open air at 500 deg C. The surface with the heater circuit and the surface on which glass was applied were brought together and bonded by being heated for 1 hour at 750 deg C. with a load of 0.5 MPa being applied to prevent shifting.

Spot facing was performed from the side opposite from the workpiece support surface to the heater circuit, with a section of the heater circuit left exposed. Active brazing metal was used to directly bond the electrodes made from W to the exposed heater circuit. The lead lines for forming electrical connections outside of the system are connected. This completes the ceramic support section.

At one end of the Al₂O₃ support body, B—Si-based glass used for bonding was applied and set so that the electrodes and lead lines can go inside. Bonding is performed by heating for 1 hour at 750 deg C. while a load of 5 kPa is applied to prevent shifting. This completes the semiconductor manufacturing device supporting unit.

As shown in FIG. 1, the supporting unit was clamped to the chamber 10 using a mullite/alumina ring so that it is mounted on the bottom of the chamber. Since clamping is the only means used to secure the structure, the end of the support body is free to thermally expand and contract radially relative to the chamber.

Ten of these semiconductor manufacturing device supporting units were produced. As in the first embodiment, thermal uniformity was measured at 700 deg C. The result was 700 deg C. ±0.90% for all supporting units. Cycling tests were also conducted as in the first embodiment and irregularities such as cracks were found in none of the supporting units.

### Seventh Embodiment

A mixture of 100 parts by weight of Si₃N₄ powder and 1.0 parts by weight of Y₂O₃ powder was prepared. Polyvinyl butyral was used as a binder, and dibutyl phthalate was used as a solvent, with 10 parts by weight and 5 parts by weight being mixed in respectively. The mixture was granulated via spray drying to form granules. These granules were processed by a single-axis press to form two sheets that, after sintering and processing, had a diameter of 350 mm and a thickness of 5 mm.

A mixture of 100 parts by weight of Si₃N₄ powder and 1.0 parts by weight of Y₂O₃ powder was prepared. Polyvinyl butyral was used as a binder, and dibutyl phthalate was used as a solvent, with 10 parts by weight and 5 parts by weight being mixed in respectively. Plasticizer and dispersant were also mixed in, and the mixture was granulated via spray drying to form granules. These granules were extruded to form a pipe shape that, after sintering and processing, formed an Si₃N₄ support body with an outer diameter of 60 mm, an inner diameter of 54 mm, and a length of 300 mm.

The shaped products were degreased in a nitrogen atmosphere at 800 deg C. and sintered for 4 hours in a nitrogen atmosphere at 1650 deg C. The obtained sintered products had a thermal conductivity of 40 W/mK. After sintering, the workpiece support surface was abraded to an Ra of 1 micron or less and the support body bonding surface was abraded to an Ra of 5 microns or less. Finishing was also performed on the outer diameters.

An Ag—Pd paste was made using 100 parts by weight of Ag—Pd powder, 1 part by weight of Y₂O₃, and 5 parts by weight of ethyl cellulose as a binder and butyl carbitol as a solvent. Mixing was performed with a pot mill and a three-roll rolling mill. This Ag—Pd paste was screenprinted on the Si₃N₄ sintered product having a 350 mm diameter to form a heater circuit pattern. This was degreased in the open air at 500 deg C. and then baked for one hour in the open air at 850 deg C.

A B—Si bonding glass in which an ethylene cellulose-based binder is added and mixed in is applied to the other Si₃N₄ sintered product with 350 mm diameter which was not printed with the heater circuit, and degreasing was performed in the open air at 500 deg C. The surface with the heater circuit and the surface on which glass was applied were brought together and bonded by being heated for 1 hour at 750 deg C. with a load of 0.5 MPa being applied to prevent shifting.

Spot facing was performed from the side opposite from the workpiece support surface to the heater circuit, with a section of the heater circuit left exposed. Active brazing metal was used to directly bond the electrodes made from W to the exposed heater circuit. The lead lines for forming electrical connections outside of the system are connected. This completes the ceramic support section.

At one end of the Si₃N₄ support body, B—Si-based glass used for bonding was applied and set so that the electrodes and lead lines can go inside. Bonding is performed by heating for 1 hour at 750 deg C. while a load of 5 kPa is applied to prevent shifting. This completes the semiconductor manufacturing device supporting unit.

As shown in FIG. 1, the supporting unit was clamped to the chamber 10 using a mullite/alumina ring so that it is mounted on the bottom of the chamber. Since clamping is the only means used to secure the structure, the end of the support body is free to thermally expand and contract radially relative to the chamber.

Ten of these semiconductor manufacturing device supporting units were produced. As in the first embodiment, thermal uniformity was measured at 700 deg C. The result was 700 deg C. ±0.70% for all supporting units. Cycling tests were also conducted as in the first embodiment and irregularities such as cracks were found in none of the supporting units.

### Eighth Embodiment

Ten units of semiconductor manufacturing device supporting units were 10 produced as described in the fifth embodiment except for replacing Ag—Pd with Pt, Ni—Cr and Mo. However, in the case of Mo, degreasing was performed in a nitrogen atmosphere at 800 deg C. and baking was performed in a nitrogen atmosphere at 1750 deg C. As in the fifth embodiment, thermal uniformity was measured at 700 deg C. The result was ±0.50% for all supporting units, which was identical to the results of the fifth embodiment. Cycling tests were also conducted as in the fifth embodiment and irregularities such as cracks were found in none of the supporting units.

Fields of Use in Industry

According to the present invention, the ceramic support section and the supporting body are hermetically bonded, the support body and the chamber are in contact with each other by way of a material having a thermal conductivity that is lower than that of the support body, or the section of the chamber that is in contact with the support body is formed from a material having a lower thermal conductivity than that of the support body. As a result, the temperature gradient of the support body is significantly changed and the temperature gradient of the connecting section between the ceramic support section and the support body is reduced. When heating, this prevents excessive strain from being applied to the connecting section between the ceramic support section and the support body, thus limiting the possibility of breakage to the ceramic support section and the support body. Also, since a material with a low thermal conductivity is interposed, the heat generated by the heat-generator tends not to escape to the chamber, thus improving the thermal uniformity of the workpiece support surface of the ceramic support section. Compared to conventional devices, semiconductor manufacturing devices in which these supporting units are installed can reduce breakage of the ceramic support section and support body and can improve the characteristics, yield, reliability, and degree of integration of semiconductors and liquid crystals.

1. In a supporting unit for semiconductor manufacturing devices including: a ceramic support section installed in a chamber of a semiconductor manufacturing device and supporting a workpiece; and a hollow support body supporting said support section;
a supporting unit for semiconductor manufacturing devices wherein said ceramic support section and said support body are hermetically bonded; and said support body and said chamber are in contact by way of a material having a thermal conductivity that is lower than that of said support body.

2. In a supporting unit for semiconductor manufacturing devices including: a ceramic support section installed in a chamber of a semiconductor manufacturing device and supporting a workpiece; and a hollow support body supporting said support section;
a supporting unit for semiconductor manufacturing devices wherein said ceramic support section and said support body are hermetically bonded; and said support body and said chamber are in contact; and a section of said chamber that is in contact with said support body is formed from a material having a thermal conductivity that is lower than that of said chamber.

3. A supporting unit for semiconductor manufacturing devices as described in claim 1 wherein said support body and said material having a thermal conductivity lower than that of said support body are bonded.

4. A supporting unit for semiconductor manufacturing devices as described in claim 1 wherein said material having a thermal conductivity lower than that of said support body has a thermal conductivity of no more than 30 W/mK.

5. A supporting unit for semiconductor manufacturing devices as described in claim 2 wherein said material having a thermal conductivity lower than that of said support body has a thermal conductivity of no more than 30 W/mK.

6. A supporting unit for semiconductor manufacturing devices as described in claim 4 wherein said material having a thermal conductivity lower than that of said support body is formed from at least one material selected from a group consisting of mullite, mullite/alumina, alumina, and stainless steel.

7. A supporting unit for semiconductor manufacturing devices as described in claim 5 wherein said material having a thermal conductivity lower than that of said support body is formed from at least one material selected from a group consisting of mullite, mullite/alumina, alumina, and stainless steel.

8. A supporting unit for semiconductor manufacturing devices as described in claim 1 wherein corrosion-resistant coating is applied to a surface of said material having a thermal conductivity lower than that of said support body.

9. A supporting unit for semiconductor manufacturing devices as described in claim 2 wherein corrosion-resistant coating is applied to a surface of said material having a thermal conductivity lower than that of said support body.

10. A supporting unit for semiconductor manufacturing devices as described in claim 8 wherein said corrosion-resistant coating is formed from alumina or aluminum nitride.

11. A supporting unit for semiconductor manufacturing devices as described in claim 9 wherein said corrosion-resistant coating is formed from alumina or aluminum nitride.

12. A supporting unit for semiconductor manufacturing devices as described in claim 1 wherein a main component of said ceramic support section is at least one material selected from a group consisting of aluminum nitride, silicon carbide, silicon nitride, and aluminum oxide.

13. A supporting unit for semiconductor manufacturing devices as described in claim 2 wherein a main component of said ceramic support section is at least one material selected from a group consisting of aluminum nitride, silicon carbide, silicon nitride, and aluminum oxide.

14. A supporting unit for semiconductor manufacturing devices as described in claim 1 wherein: a heating element is formed in said ceramic support section; and a main component of said heating element is at least one material selected from a group consisting of tungsten (W), molybdenum (Mo), platinum (Pt), silver (Ag), palladium (Pd), nickel (Ni), and chrome (Cr).

15. A supporting unit for semiconductor manufacturing devices as described in claim 2 wherein: a heating element is formed in said ceramic support section; and a main component of said heating element is at least one material selected from a group consisting of tungsten (W), molybdenum (Mo), platinum (Pt), silver (Ag), palladium (Pd), nickel (Ni), and chrome (Cr).

16. A semiconductor manufacturing device in which is installed a supporting unit for semiconductor manufacturing devices as described in claim 1.

17. A semiconductor manufacturing device in which is installed a supporting unit for semiconductor manufacturing devices as described in claim 2.
